(19) United States
(12) Patent Application Publication
(10) Pub. No.: US 2013/0320362 A1
(43) Pub. Date: Dec. 5, 2013

(54) HIGH VOLTAGE LIGHT EMITTING DIODE PACKAGE AND METHOD FOR MANUFACUTING THE SAME

(71) Applicant: ADVANCED OPTOELECTRONIC TECHNOLOGY, INC., Hsinchu Hsien (TW)

(72) Inventors: CHIEN-CHUNG PENG, Hukou (TW); TZU-CHIEN HUNG, Hukou (TW); CHIA-HUI SHEN, Hukou (TW)

(73) Assignee: ADVANCED OPTOELECTRONIC TECHNOLOGY, INC., Hsinchu Hsien (TW)

(21) Appl. No.: 13/868,109

(22) Filed: Apr. 23, 2013

(30) Foreign Application Priority Data
May 30, 2012 (CN) 2012101728479

(51) Int. Cl. H01L 33/22

(52) U.S. Cl. CPC H01L 33/22
USPC 257/88; 438/27

(57) ABSTRACT

A high voltage LED package includes a substrate and LED chips formed on a top surface of the substrate. A periphery of each LED chip is roughened. The LED chips are electrically connected in series.

### BACKGROUND

1. Technical Field

The disclosure generally relates to semiconductors, and more particular to a light emitting diode (LED) package and manufacturing method for the LED package, wherein the LED package is a high voltage LED package which has improved light extraction efficiency.

2. Description of Related Art

LEDs have many beneficial characteristics, including low electrical power consumption, low heat generation, long lifetime, small volume, good impact resistance, fast response and excellent stability. These characteristics have enabled the LEDs to be widely used as a light source in electrical appliances and electronic devices.

An LED chip is driven to generate light by a direct current of 1.5-4 voltages, whereby a rectifier which can convert an alternative current to a direct current and a converter which can lower the generally high voltage of main electrical power of 110V AC in Taiwan or 120V AC in USA to 1.5-4V DC is required. To simplify the circuit, a plurality of LED chips are packaged together which are serially connected together to construct a high voltage LED (HV LED) package, whereby the main electrical power can be directly used to drive the HV LED to lighten only if the main electrical power is rectified to be a direct current.

The HV LED package includes a substrate and a plurality of LED chips on the substrate wherein each LED chip includes an epitaxial layer formed on the substrate. Outer surfaces of the epitaxial layer are planar. Light emitted from the epitaxial layer traverses through the outer surfaces to illuminate. Because the outer surfaces are planar, the incidence light oriented towards the outer surfaces will be parallel reflected. When an incidence angle of a part of light is larger than the critical angle of the epitaxial layer, a total internal reflection is occurred. The part of light is reflected back to an interior of the epitaxial layer and can not be used to illuminate. Thus, luminance of the HV LED package is limited.

What is needed is an HV LED package which can overcome the problem of the prior art.

### BRIEF DESCRIPTION OF THE DRAWINGS

FIG. 1 is a cross sectional view of an HV LED package according to an exemplary embodiment of the present disclosure.

FIGS. 2-9 are schematic views showing steps of a method for manufacturing the HV LED package of FIG. 1.

### DETAILED DESCRIPTION

An embodiment of an HV LED package in accordance with the present disclosure will now be described in detail below and with reference to the drawings.

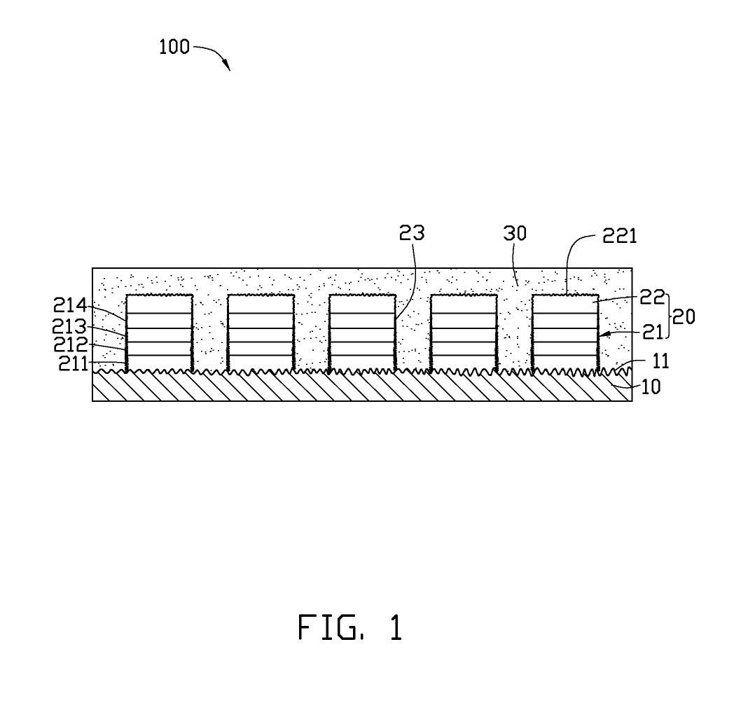

Referring to FIG. 1, an HV LED package 100 in accordance with an exemplary embodiment of the disclosure includes a substrate 10, a plurality of LED chips 20 formed on the substrate 10, and a packaging layer 30 mounted on the substrate 10 and enclosing the LED chips 20 therein. The LED chips 20 are electrically connected together in series.

A material of the substrate 10 is selected from sapphire, silicone, silicon carbide, gallium arsenide, lithium aluminum, magnesium oxide, zinc oxide, gallium nitride, aluminum nitride, indium nitride. The substrate 10 is rectangular. A plurality of continuous protrusions 11 is formed on a top surface of the substrate 10 to roughen the top surface of the substrate 10.

The LED chips 20 are arrayed on the protrusions 11 and electrically connect with a circuit formed on the substrate 10. Each LED chip 20 includes an epitaxial portion 21 and a diffusion portion 22 formed on a top end of the epitaxial portion 21. The epitaxial portion 21 includes a buffer layer 211, a P-type semiconductor layer 212, an active layer 213, and an N-type semiconductor layer 214 arranged on the substrate 10 in sequence from bottom to top. A plurality of continuous protrusions 23 is formed on a periphery 20a of the LED chip 20 to roughen the periphery 20a of the LED chip 20.

The diffusion portion 22 is transparent and formed on the N-type semiconductor layer 214. The diffusion portion 22 is configured for evenly distributing current over the N-type semiconductor layer 214. A plurality of continuous protrusions 221 is formed on a top surface of the diffusion portion 22 to roughen the diffusion portion 22.

The packaging layer 30 is made of a mixture. The mixture includes a transparent base material and a plurality of phosphor powders evenly distributed in the transparent base material. The transparent base material is selected from silicone, epoxy, and silicone acrylate resin. A material of the powders is selected from yttrium aluminum garnet (YAG), terbium doped YAG and so on.

In this disclosure, because the periphery 20a and the top surface of the diffusion portion 22 are roughened, the light emitted from the active layer 213 can be reflected several times by the periphery 20a and the diffusion portion 22. The incidence angle of the light is changed with the reflection. Thus, a part of light total reflected back to the interior of the conventional LED package will traverse through the periphery 20a and the diffusion portion 22 to illuminate. Therefore, luminance of the HV LED package 100 is improved. Furthermore, the protrusions 11 of the substrate 10 can reflects light oriented thereto to different directions to change the incidence angle of the light to further improve luminance of the HV LED package 100.

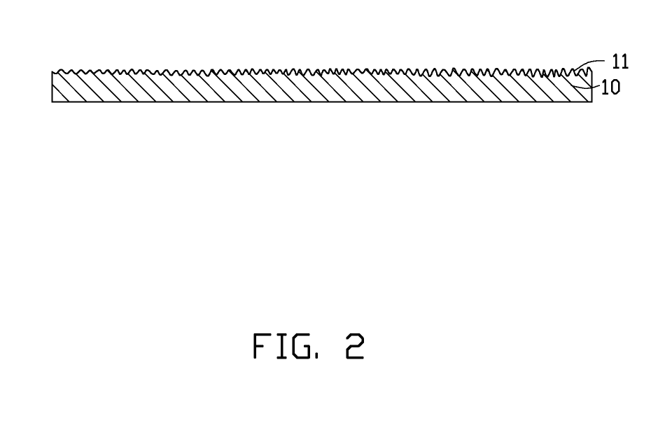

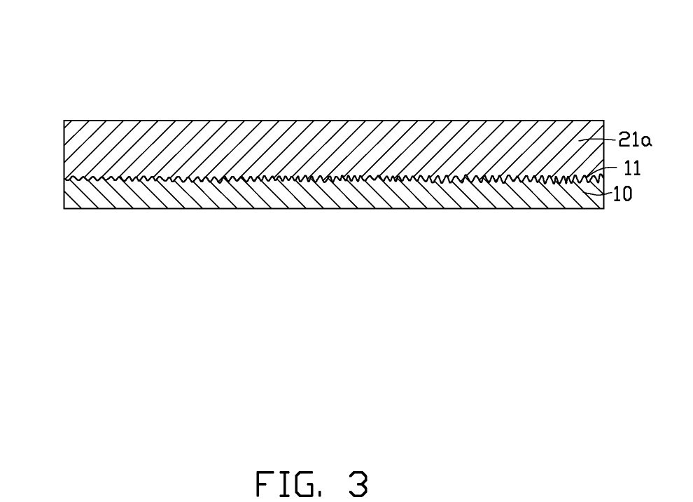

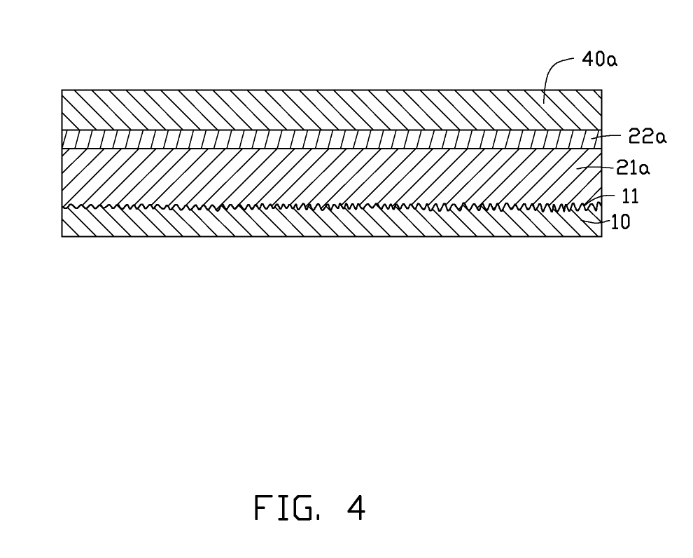

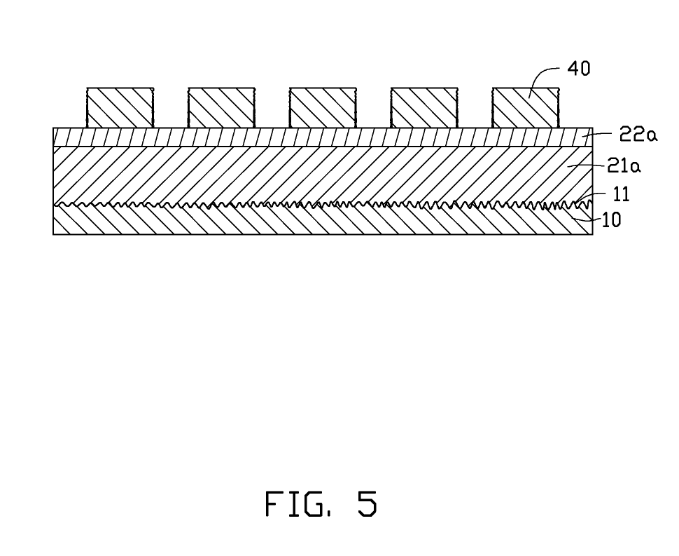

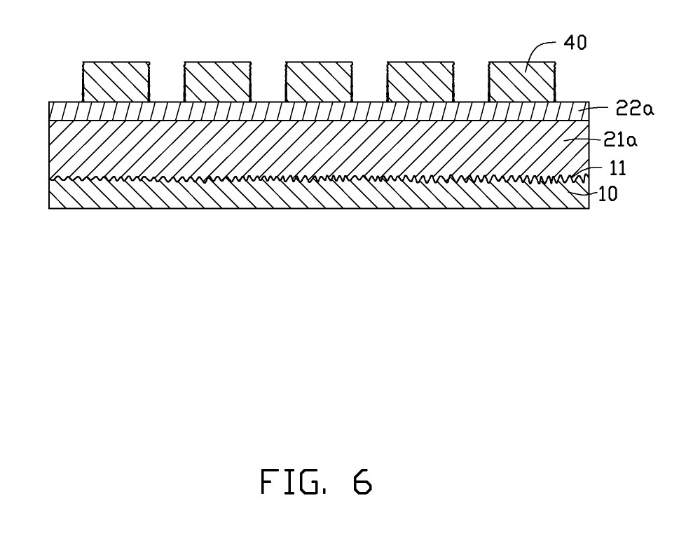

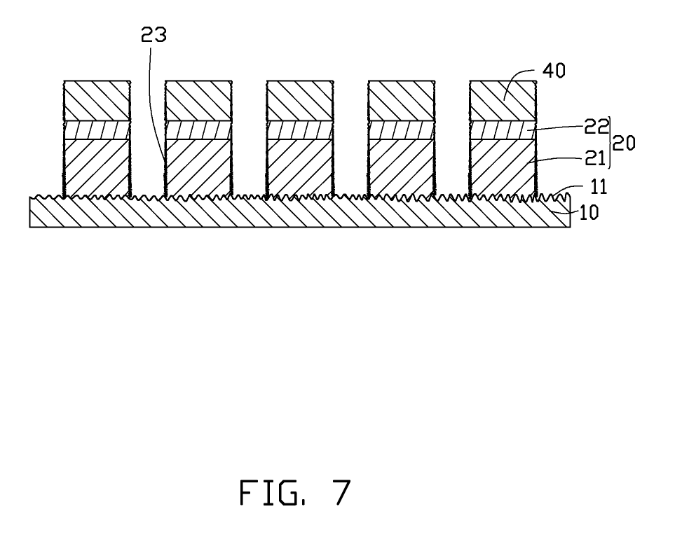

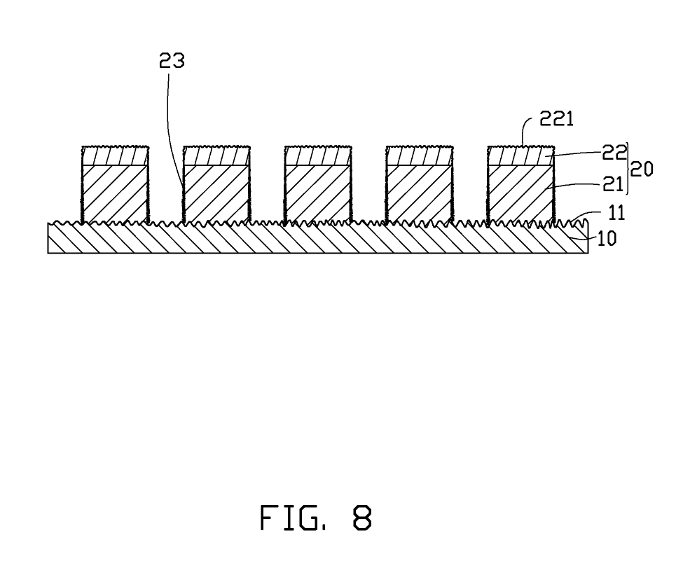

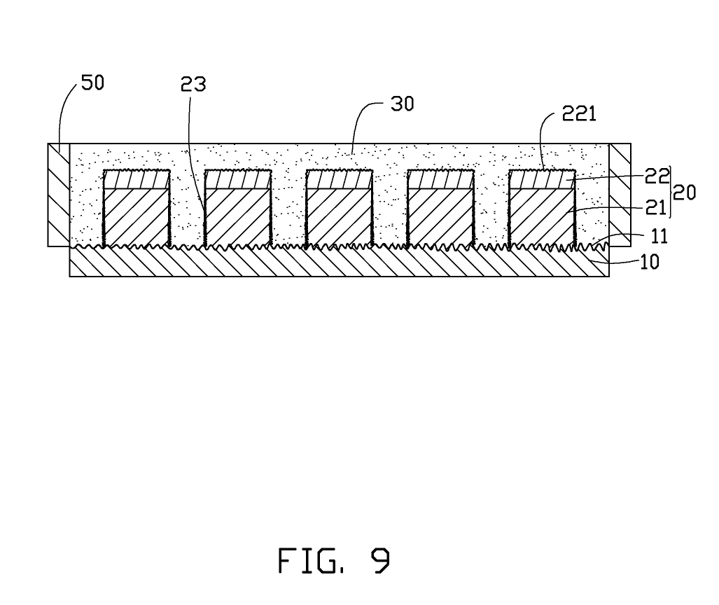

Referring to FIGS. 2-9, a method for manufacturing the HV LED package 100 in accordance with the disclosure is as follows.

The first step is providing the substrate 10 and etching the top surface of the substrate 10 by acid solution until the protrusions 11 are obtained thereon.

The second step is growing an epitaxial layer 21a on the protrusions 11.

The third step is forming a diffusion layer 22a on a top end of the epitaxial layer 21a.

The fourth step is forming an elongated photoresist layer 40a on a top end of the diffusion layer 22a. The photoresist layer 40a is Propylene Glycol Mono-methyl Ether Acetate (PGMEA), Polymethylmethacrylate (PMMA) or a combination thereof.

The fifth step is etching the photoresist layer 40a to divide the photoresist layer 40a into a plurality of spaced photoresist portions 40 and patterning (roughening) a periphery of each photoresist portion 40 simultaneously. In this step, the photoresist layer 40a is etched through along a height direction of the LED package 100 to expose a part of a top end of the diffusion portion 22a. The photoresist layer 40a is etched by acid solution or irradiation of yellow light.

The sixth step is etching the diffusion layer 22a and the epitaxial layer 21a along the height direction of the HV LED package 100 from spaces between the photoresist portions 40 until the epitaxial layer 21a is divided into a plurality of epitaxial portions 21 and the diffusion layer 22a is divided into a plurality of diffusion portions 22, whereby the pattern of the periphery of the photoresist portion 40 is continuously extended to a periphery of the diffusion portion 22 and a periphery of the epitaxial portion 21. The epitaxial portion 21 and the diffusion portion 22 are formed the LED chip 20. The protrusions 23 are formed on the periphery 20a of the LED chip 20.

The seventh step is taking off the photoresist portions 40 and etching the top end of the diffusion portion 22 by acid solution until the protrusions 221 are obtained on the top end of the diffusion portion 22.

The eighth step is providing a hollow mold 50 and mounting the mold 50 on the substrate 10 to make the mold 50 surround the LED chips 20 therein.

The ninth step is providing a mixture formed by a transparent base material and a plurality of phosphor powders evenly mixed with the transparent base material and injecting the mixture in the mold 50 and heating the mixture to make the mixture be solidified to obtain the packaging layer 30.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An HV LED (high voltage light emitting diode) package comprising:
a substrate; and
a plurality of LED chips formed on a top surface of the substrate, the LED chips being electrically connected together in series, a periphery of each LED chip being roughened.

2. The HV LED package of claim 1, wherein a plurality of continuous protrusion is formed on the periphery of each LED chip to roughen the periphery of each LED chip.

3. The HV LED package of claim 2, wherein each LED chip comprises an epitaxial portion and a diffusion portion formed on a top end of the epitaxial portion, and a periphery of the epitaxial portion and a periphery of the diffusion portion are roughened.

4. The HV LED package of claim 3, wherein a top surface of the diffusion portion is roughened.

5. The HV LED package of claim 4, wherein a plurality of continuous protrusions is formed on the top surface of the diffusion portion.

6. The HV LED package of claim 1, wherein the top surface of the substrate is roughened.

7. The HV LED package of claim 6, wherein a plurality of continuous protrusions is formed on the top surface of the substrate, and the LED chips are formed on the protrusions.

8. The HV LED package of claim 7, wherein a packaging layer is mounted on the substrate and encloses the LED chips therein.

9. A method for manufacturing an HV LED (high voltage light emitting diode) package comprising following steps:
providing a substrate;
growing an epitaxial layer on the substrate;
forming a diffusion layer on a top end of the epitaxial layer;
forming a photoresist layer on a top end of the diffusion layer;
etching the photoresist layer along a height direction of the LED package to divide the photoresist layer into a plurality of spaced photoresist portions and patterning a periphery of each photoresist portion simultaneously; and
etching the diffusion layer and the epitaxial layer along the height direction of the LED package from spaces between the photoresist portions until the epitaxial layer is divided into a plurality of epitaxial portions and the diffusion layer is divided into a plurality of diffusion portions, wherein the pattern of the periphery of each photoresist portion is continuously extended to a periphery of a corresponding diffusion portion and a periphery of a corresponding epitaxial portion, and wherein the epitaxial portions are electrically connected together in series.

10. The method of claim 9, wherein the photoresist layer is etched by acid solution or irradiation of yellow light.

11. The method of claim 9, wherein before growing the epitaxial layer, the top surface of the substrate is etched to form a plurality of protrusions thereon.

12. The method of claim 11, wherein the substrate is etched by acid solution.

13. The method of claim 9 further comprising following steps, taking off the photoresist portions and etching the top end of each diffusion portion to roughen the top end of each diffusion portion.

14. The method of claim 13, wherein the diffusion portion is etched by acid solution.

15. The method of claim 13 further comprising following steps, providing a hollow mold and mounting the mold on the substrate to make the mold surround the epitaxial portions and the diffusion portions therein, providing a mixture, injecting the mixture in the mold and heating the mixture to make the mixture be solidified to obtain a packaging layer enclosing the epitaxial portions and the diffusion portions therein.

16. The method of claim 15, wherein the mixture is formed by a transparent base material and a plurality of phosphor powders evenly mixed with the transparent base material.

17. The method of claim 16, wherein the transparent base material is selected from silicone, epoxy, and silicone acrylate resin.

18. The method of claim 16, wherein a material of the powders is selected from yttrium aluminum garnet (YAG) and terbium doped YGA.

19. The method of claim 9, wherein the photoresist layer is Propylene Glycol Mono-methyl Ether Acetate (PGMEA), Polymethylmethacrylate (PMMA) or a combination thereof.
